(19) United States
(12) Patent Application Publication
(10) Pub. No.: US 2004/0191568 A1
(43) Pub. Date: Sep. 30, 2004

(54) Organic EL panel and method of manufacturing the same

(75) Inventors: Isamu Ohshita, Yamagata-ken (JP); Takemi Naito, Yamagata-ken (JP); Atsusi Matsuda, Yamagata (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: Tohoku Pioneer Corporation

(21) Appl. No.: 10/799,593

(22) Filed: Mar. 15, 2004

(30) Foreign Application Priority Data
Mar. 26, 2003 (JP) 2003-85418

(51) Int. Cl. H05B 33/04

(52) U.S. Cl. 428/690; 428/917; 428/156; 313/512; 257/100; 156/67

(57) ABSTRACT

It is an object of the invention to avoid a contact between desiccating member(s) provided within a cover and an organic EL laminated body. An organic EL panel includes a substrate and an organic EL laminated body formed on the substrate. The organic EL laminated body includes a first electrode, an organic layer, and a second electrode, laminated one above another, with the organic layer interposed between the pair of electrodes, thereby forming an organic EL device. Further, a cover is bonded to the substrate by virtue of an adhesive agent, thereby covering the organic EL laminated body with the cover so as to protect the same from the outside air. Moreover, a desiccating member is provided within the cover 16 and separated from the organic EL laminated body. A concave portion U is formed on the exposed side (facing the organic EL laminated body) of the desiccating member.

### BACKGROUND OF THE INVENTION

The present invention relates to an organic EL (electroluminescent) panel and a method of manufacturing the organic EL panel.

The present application claims priority from Japanese Application No. 2003-85418, the disclosure of which is incorporated herein by reference.

An organic EL panel comprises an organic EL device serving as its essential component and including a first electrode formed on a substrate, an organic layer (containing a luminescent layer consisting of an organic compound) formed on the first electrode, and a second electrode formed on the organic layer. The organic EL device is used as a luminescent unit and arranged on the substrate.

It has been known that an organic EL panel will get deteriorated in its characteristics once its organic layer and its electrodes are exposed to the outside air. This is because if moisture enters an interface between the organic layer and the electrodes, electron injection will be hampered. As a result, dark spots (which are non-luminescent areas) will occur and the electrodes are corroded. In order to improve the stability and durability of the organic EL device, it is necessary to establish an encapsulation technique for protecting the organic EL device from the outside air. Specifically, an encapsulation technique usually requires that a cover for covering the electrodes and the organic layer is bonded (by virtue of an adhesive agent) to the substrate on which the electrodes and organic layer have already been formed.

FIGS. 1A and 1B show an organic EL panel formed according to a prior art (Japanese Unexamined Patent Application Publication No. Hei 9-148066). FIG. 1A is a cross sectional view showing the structure of the organic EL panel. As shown, the conventional organic EL panel 1 comprises i) a glass substrate 2, ii) a laminated body (an organic EL laminated body) 6 consisting of an ITO electrode (a first electrode) 3 serving as an anode, an organic luminescent layer (organic layer) 6, and a cathode (a second electrode) 5, iii) a glass cover 7, iv) a desiccating member 8, and v) a sealing material (adhesive agent) 9.

The desiccating member 8 is provided to absorb and thus remove initial moisture and later moisture generated with the passing of time or entered from the outside (all after the glass cover 7 has been bonded to the glass substrate 2). Particularly, since the organic layer partially forming the organic EL device is not resistant to heat, it is not allowed to remove the moisture by carrying out a heating treatment before encapsulation (bonding the cover 7 to the glass substrate 2), hence making it impossible to completely remove the initial moisture. For this reason, the desiccating member 8 has to be introduced into the cover of an organic EL panel formed by using the present organic EL material. Japanese Unexamined Patent Application Publication No. Hei 9-148066 discloses an organic EL panel containing the desiccating member 8 which is a compound capable of chemically absorbing moisture and maintaining its solid state even after having absorbed the moisture. Such desiccating member 8 is attached to inner surface of the glass cover 7, fixed thereon by virtue of an adhesive material, and spaced apart from the laminated body 6.

FIG. 1B is an explanatory view showing a problem existing in the above-described prior art. Namely, in the above-described organic EL panel, once the desiccating member 8 absorbs moisture or the like, it will expand in its volume, resulting in a situation in which the central portion 8A of the desiccating member 8 expands into a convex shape. On the other hand, since an organic EL panel is usually required to be made thin in its thickness, an inner space of the cover (glass cover 7) should be made as thin as possible. However, in order to ensure a sufficient function of moisture removal, the desiccating member 8 is still required to have a certain thickness. As a result, an interval between the laminated body 6 and the desiccating member 8 within the organic EL panel 1 becomes narrow. Consequently, as shown in FIG. 1B, when the central portion 8A of the desiccating member 8 disposed opposite to the laminated body 6 expands into a convex state, the desiccating member 8 will get close to the electrode surface of the laminated body 6. At this time, if the organic EL panel has deformed to some extent for some reason, there is a possibility that the laminated body 6 will get into contact with the desiccating member 8.

Once the above problem occurs, deterioration factors such as moisture absorbed by the desiccating member 8 will migrate to the laminated body 6 due to a surface tension, hence deteriorating the electrode sand the organic layer of the laminated body 6. As a result, the working life of the organic EL panel will be remarkably shortened.

### SUMMARY OF THE INVENTION

The present invention has been accomplished in view of the above-discussed problem, and it is an object of the invention to ensure a sufficient working life of an organic EL panel, by avoiding an undesired contact between a laminated body (hereinafter referred to as organic EL laminated body) forming an organic EL device and a desiccating member provided within a cover, without increasing the thickness of the panel.

In one aspect of the invention, there is provided a an organic EL panel having a substrate and an organic EL laminated body formed on the substrate, said organic EL laminated body being formed by interposing at least one organic layer between a pair of electrodes, said organic EL panel further including a cover for protecting the organic EL laminated body from the outside air, characterized in that: a least one desiccating member is provided within the cover and separated from the organic EL laminated body; and a concave portion is formed on one surface of the desiccating member, said one surface being orientated to face the organic EL laminated body.

In another aspect of the invention, there is provided a method of manufacturing an organic EL panel, including device formation step of forming, on a substrate, an organic EL laminated body including a pair of electrodes and at least one organic layer interposed between the pair of electrodes; and encapsulation step of bonding a cover to the substrate for protecting the organic EL laminated body from the outside air, characterized in that: at least one desiccating member is introduced into the cover prior to the encapsulation step; and a concave portion is formed on one surface of the desiccating member, said one surface being orientated to face the organic EL laminated body.

### BRIEF DESCRIPTION OF THE DRAWINGS

These and other objects and advantages of the present invention will become clear from the following description with reference to the accompanying drawings, wherein:

FIGS. 1A and 1B are cross sectional views showing an organic EL panel according to a prior art;

FIGS. 2A and 2B are cross sectional views showing an organic EL panel according to one embodiment of the present invention;

FIGS. 3A and 3B are cross sectional views showing an organic EL panel according to another embodiment of the present invention;

FIGS. 4A and 4B are cross sectional views showing an organic EL panel according to a further embodiment of the present invention;

FIGS. 5A and 5B are cross sectional views showing an organic EL panel according to one more embodiment of the present invention.

FIGS. 6A-6C are cross sectional views showing the cross sections of several different desiccating members according to an embodiment of the present invention;

FIGS. 7A-7D are plan views showing the outer appearances of several different desiccating members according to an embodiment of the present invention;

FIGS. 8A and 8B are explanatory views showing a desiccating member according to an embodiment of the present invention;

FIGS. 9A and 9B are cross sectional views showing an organic EL panel according to a further embodiment of the present invention; and

FIG. 10 is a flow chart briefly showing a process of manufacturing an organic EL panel according to an embodiment of the present invention.

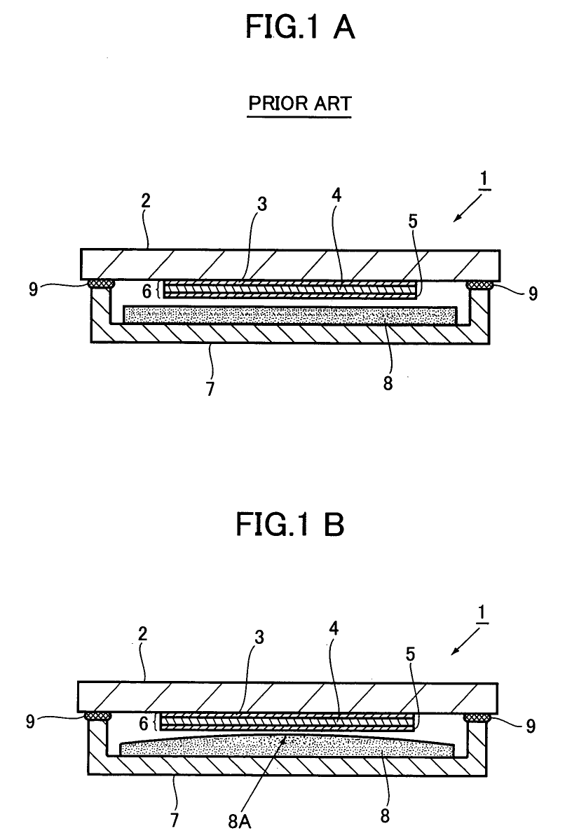

### DETAILED DESCRIPTION OF THE PREFERRED EMBODIMENTS

Several embodiments of the present invention will be described in the following with reference to the accompanying drawings.

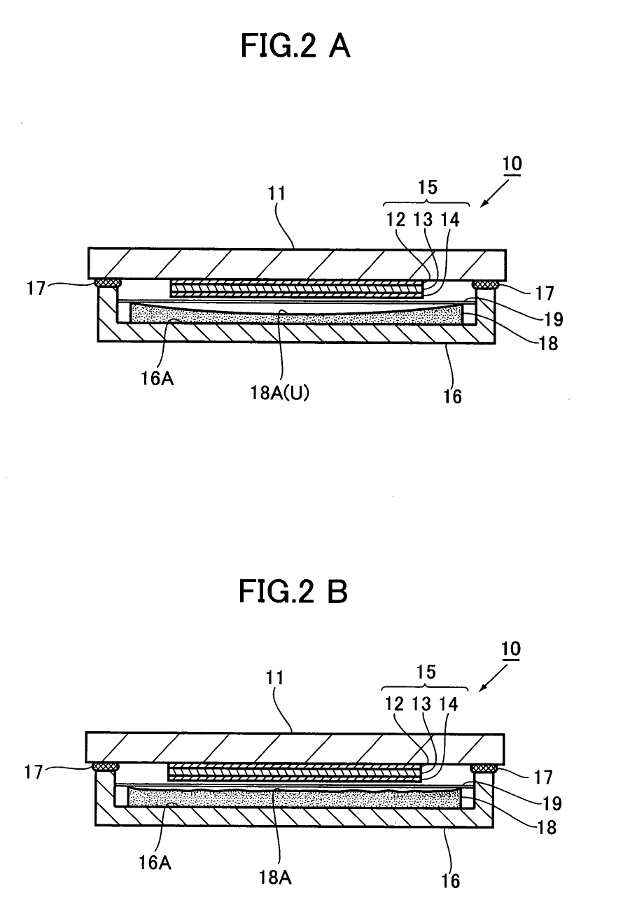

FIGS. 2A and 2B are explanatory views showing an organic EL panel formed according to one embodiment of the present invention. FIG. 2A shows an organic EL panel 10 which has just been manufactured. As shown, the organic EL panel 10 has a substrate 11 and an organic EL laminated body 15 (including a first electrodes 12, an organic layer 13, and a second electrode 14 laminated one above another) formed on the substrate 11. In fact, the organic EL laminated body 15 forms an organic EL device including a pair of electrodes and at least an organic layer interposed between the electrode pair. Here, a cover 16 is bonded to the substrate 11 by virtue of an adhesive agent 17, thereby covering the organic EL laminated body 15 with the cover 16 by shutting off the outside air. At this time, a desiccating member 18 has already been introduced into the cover 16 and separated from the organic EL laminated body 15. Meanwhile, a concave portion has been formed on the exposed side 18A (facing the organic EL laminated body 15) of the desiccating member 18.

The desiccating member 18 is provided to absorb and thus remove initial moisture and later moisture generated with the passing of time or entered from the outside (all after the glass cover 16 has been bonded to the glass substrate 11). In fact, the desiccating member 18 should not receive any limitation, provided that it has the required function. As one example, it is allowed to use a hygroscopic molded body (to be described later) having a concave portion U, and attach the hygroscopic molded body to the inner surface 16A of the cover 16 in a manner shown in FIG. 2A, with the concave portion U formed on the exposed side 18A facing the organic EL laminated body 15. Besides, if necessary, a drop prevention sheet 19 (for preventing the desiccating member 18 from falling down) can be provided between the desiccating member 18 and the organic EL laminated body 15.

FIG. 2B shows a situation in which the desiccating member 18 of the organic EL panel 10 has already absorbed moisture. In the organic EL panel 10 of the present embodiment, since the concave portion U is formed on the exposed side 18A (facing the organic EL laminated body 15) of the desiccating member 18, even if the desiccating member 18 expands because it absorbs moisture, the exposed side 18A of the desiccating member 18 would not project towards the organic EL laminated body 15. Therefore, it is possible to constantly keep an interval between the organic EL laminated body 15 and the desiccating member 18 at a distance which is equal to or larger than a predetermined value, there by avoiding an undesired contact between the organic EL laminated body 15 and the desiccating member 18.

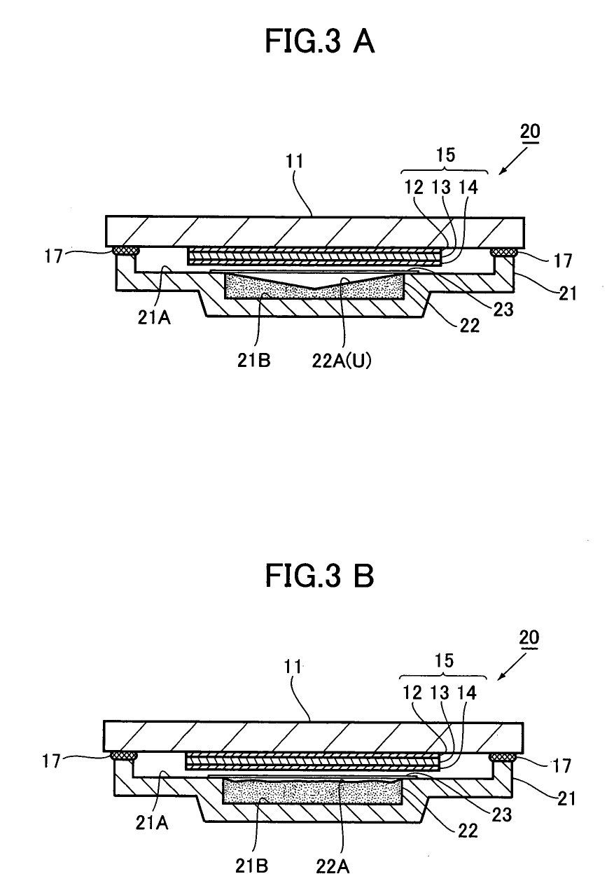

FIGS. 3A and 3B are explanatory views showing an organic EL panel formed according to another embodiment of the present invention (however, the elements which are the same as those in the above embodiment will be represented by the same reference numerals and similar description will be omitted). FIG. 3A shows an organic EL panel 20 which has just been manufactured. As shown, the organic EL panel 20 includes a substrate 11, an organic EL laminated body 15 formed on the substrate 11, and a cover 21. By bonding the cover 21 to the substrate 11 using an adhesive agent 17, the organic EL laminated body 15 can be covered by the cover 21, thereby protecting the organic EL laminated body 15 from the outside air. Moreover, formed on the inner surface 21A of the cover 21 is a pocket-like attachment section 21B for fixing a desiccating member 22.

Attached to the attachment section 21B is the desiccating member 22 spaced from the organic EL laminated body 15. A concave portion U is formed on the exposed side 22A (facing the organic EL laminated body 15) of the desiccating member 22. Similarly, the desiccating member 22 is provided to absorb and thus remove initial moisture and later moisture generated with the passing of time or entered from the outside (all after the glass cover 21 has been bonded to the glass substrate 11). In fact, the desiccating member 22 should not receive any limitation, provided that it has the required function. As one example, it is allowed to use a hygroscopic molded body (to be described later) having a concave portion U, and attach the hygroscopic molded body to the attachment section 21B of the cover 21 in a manner shown in FIG. 3A, with the concave portion U formed on the exposed side 22A facing the organic EL laminated body 15. Besides, if necessary, a drop prevention sheet 23 (for clogging the attachment section 21B) can be provided between the desiccating member 22 and the organic EL laminated body 15.

FIG. 3B shows a situation in which the desiccating member 22 of the organic EL panel 20 has absorbed moisture. In the organic EL panel 20 of the present embodiment, since the concave portion U is formed on the exposed side 22A (facing the organic EL laminated body 15) of the desiccating member 22, even if the desiccating member 22 expands because it absorbs moisture, the exposed side 22A of the desiccating member 22 would not project towards the organic EL laminated body 15. Therefore, it is possible to constantly keep an interval between the organic EL laminated body 15 and the desiccating member 22 at a distance which is equal to or larger than a predetermined value, thereby avoiding an undesired contact between the organic EL laminated body 15 and the desiccating member 22.

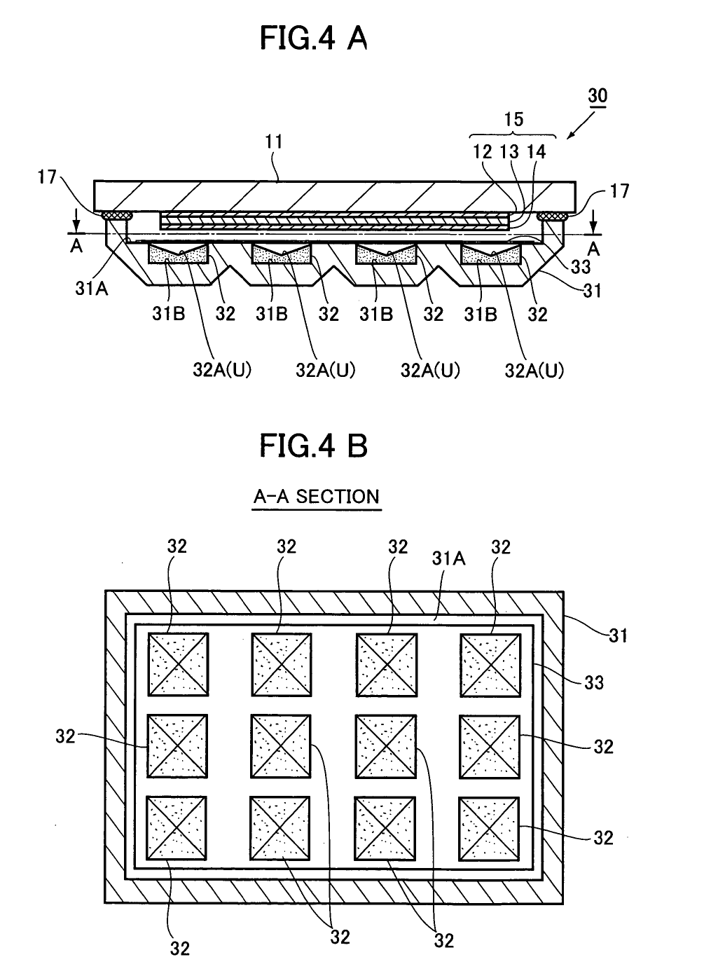

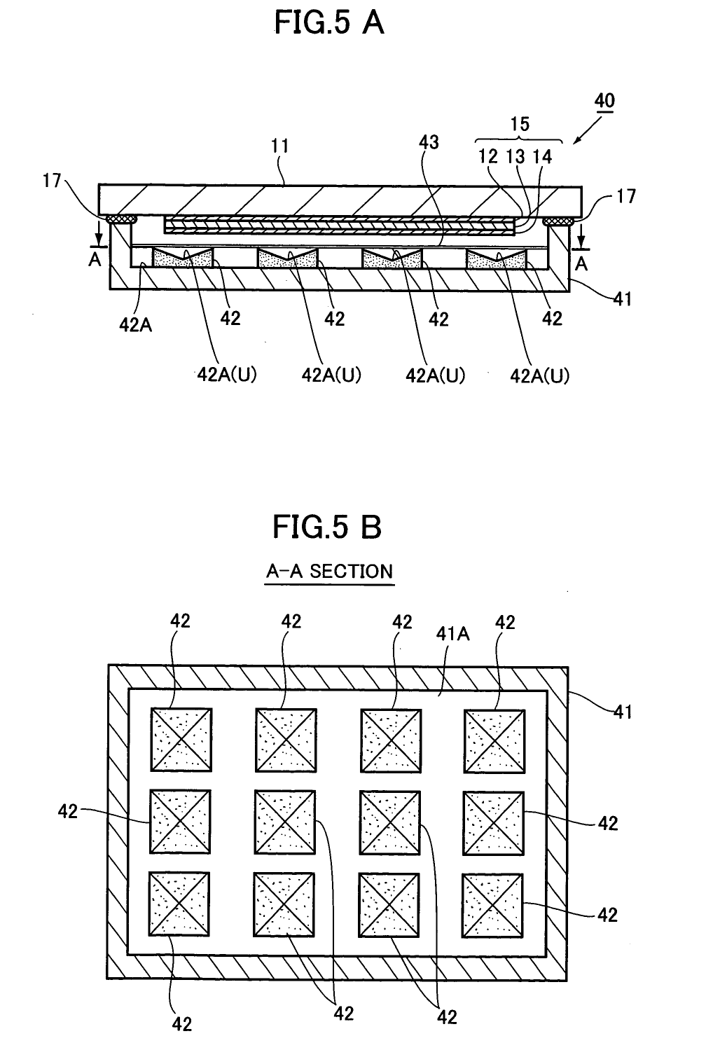

FIGS. 4 and 5 are cross sectional views showing organic EL panels formed according to further embodiments of the present invention (however, the same elements as those in the above embodiments will be represented by the same reference numerals and similar description will be omitted). FIG. 4A is a cross sectional view showing an organic EL panel 30 which has just been manufactured. FIG. 4B is another cross sectional view taken along A-A line in FIG. 4A. As shown, the organic EL panel 30 is fabricated such that a plurality of attachment sections 31B (each similar to those discussed in the above-described embodiments) are formed on the inner surface 31A of a cover 31. Each attachment section 31B contains a desiccating member 32 (similar to those discussed in the above-described embodiments) separated from the organic EL laminated body 15. Further, each desiccating member 32 is a hygroscopic molded body having a concave portion formed on its exposed side 32A facing the organic EL laminated body 15. Besides, if necessary, a drop prevention sheet 32 (for clogging the attachment sections 31B) can be provided between the desiccating members 32 and the organic EL laminated body 15.

FIG. 5A is a cross sectional view showing an organic EL panel 40 which has just been manufactured. FIG. 5B is another cross sectional view taken along A-A line in FIG. 5A. As shown, the organic ELpanel 40 is fabricated such that a plurality of desiccating members 42 are attached to the inner surface 41A of a cover 41. Further, similar to those discussed in the above-described embodiments, each desiccating member 42 is a hygroscopic molded body having a concave portion U formed on its exposed side 42A facing the organic EL laminated body 15. Besides, if necessary, a drop prevention sheet 43 can be provided between the desiccating members 42 and the organic EL laminated body 15.

In such organic EL panels 30 and 40, since the concave portions U are formed on the exposed sides 32A and 42A (facing the organic EL laminated body 15) of the desiccating members 32 and 42, even after the desiccating members 32 and 42 have absorbed moisture and thus expanded, the concave portions U will absorb such an expansion, thereby preventing the exposed sides 32A and 42A from protruding towards the organic EL laminated body 15. In this way, it is possible to constantly keep an interval between the organic EL laminated body 15 and the desiccating members 32, 42 at a distance which is equal to or larger than a predetermined value, thereby avoiding an undesired contact between the organic EL laminated body 15 and the desiccating members 32, 42.

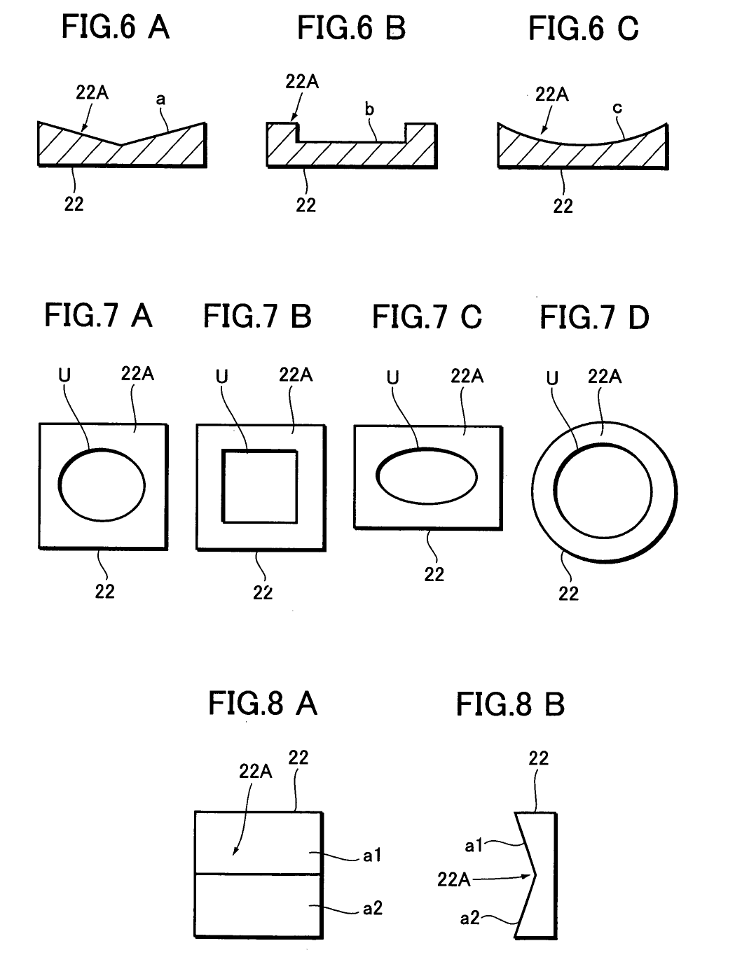

FIGS. 6A-8B illustrate various shapes of the desiccating members 18, 22, 32, and 42 (hereafter, represented by reference numeral 22) used in the above-described embodiments. However, the present invention should not be limited to these shapes, but can have any other shapes, provided that each desiccating member has a concave portion formed at least in its central position and facing the organic EL laminated body 15.

FIGS. 6A-6C are cross sectional views showing the cross sections of several differently shaped desiccating members. FIG. 6A shows an example in which two inclined surfaces are formed on the exposed side 22A of a desiccating member to form a concave portion. FIG. 6B shows an example in which a concave portion (containing a bottom surface b) is formed on the exposed side 22A of a desiccating member. FIG. 6C shows an example in which a curved surface c is formed on the exposed side 22A of a desiccating member to form a concave portion.

FIGS. 7A-7D are plan views showing several differently shaped desiccating members. FIG. 7A shows an example in which a generally circular concave portion U is formed on the exposed side 22A of a generally rectangular desiccating member. FIG. 7B shows an example in which a generally square concave portion U is formed on the exposed side 22A of a generally square desiccating member. FIG. 7C shows an example in which an elliptical concave portion is formed on the exposed side 22A of a rectangular desiccating member. FIG. 7D shows an example in which a circular concave portion is formed on the exposed side 22A of a circular desiccating member.

Moreover, it is also possible to form two inclined surfaces a1, a2 on the exposed side 22A of a desiccating member such that the exposed surface becomes hollow in only one direction, as shown in FIG. 8 (FIGS. 8A is a plan view and 8B is a side view).

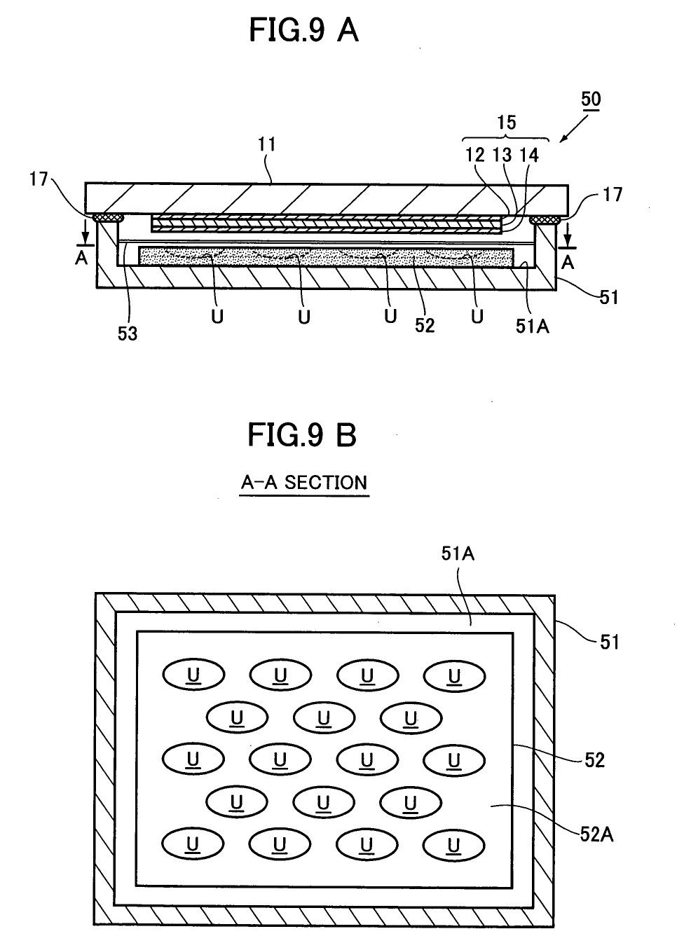

FIG. 9A is a cross sectional view showing an organic EL panel 50 which has just been manufactured. FIG. 9B is another cross sectional view taken along A-A line in FIG. 9A. As shown, the organic EL panel 50 is fabricated such that an overall desiccating member 52 is attached to the entire inner surface 51A of a cover 51. In fact, the desiccating member 52 is a hygroscopic molded body having a plurality of concave portions U formed on its exposed side. In this way, surface 52A facing the organic EL laminated body 15 is formed by virtue of the surface including the plurality of concave portions U. Besides, if necessary, it is allowed to provide a drop prevention sheet 53 between the desiccating member 52 and the organic EL laminated body 15.

Actually, the present embodiment can provide the same effect as the above-described embodiments. Namely, since a plurality of concave portions U are formed on the exposed side 52A (facing the organic EL laminated body 15) of the desiccating member 52, even if the desiccating member 52 expands because it absorbs moisture, the plurality of concave portions will absorb such an expansion, making it sure that the exposed side 52A of the desiccating member 52 would not project towards the organic EL laminated body 15. Therefore, it is possible to constantly keep an interval between the organic EL laminated body 15 and the desiccating member 52 at a distance which is equal to or larger than a predetermined value, thereby avoiding an undesired contact between the organic EL laminated body 15 and the desiccating member 52.

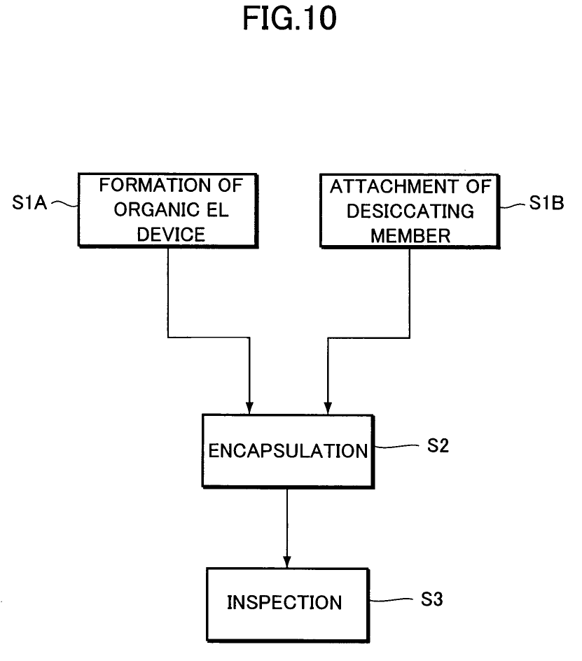

Next, description will be given to explain a method for manufacturing an organic EL panel according to the present invention. FIG. 10 is a flow chart showing a related manufacturing process. At first, at step SIA of forming an electroluminescent device, the organic EL laminated body 15 including the first electrode 12, the organic layer 13, and the second electrode 14 is formed on the substrate 11, thereby forming the organic EL device including a pair of electrodes and an organic layer interposed between the electrode pair. Here, the formation of the organic EL device may be accomplished by using a well-known film formation process and a patterning process.

Then, at step SIB of attaching a desiccating member, a desiccating member 18, 22, 32, 42, or 52 (hereinafter, represented by a reference numeral 22) is attached to the inner surface of a cover 16, 21, 31, 41, or 51 (hereinafter, represented by a reference numeral 21), followed by attaching a drop prevention sheet 19, 23, 33, 43, or 53. Specifically, at step SIB of attaching a desiccating member, at first, a concave portion U is formed on the exposed side 22A (facing the organic EL laminated body 15) of the desiccating member 22. Here, if the desiccating member 22 is formed by a hygroscopic molded body, it is allowed to employ a mold capable of forming a desiccating member having a desired concave portion. Besides, it is also possible to at first form a desiccating block having a predetermined appearance and then press a convex mold (corresponding to a desired concave portion) against the desiccating block, thereby forming a desiccating member having a desired concave portion. Next, the formed desiccating member 22 is attached to the inner surface of the cover 21.

Next, at an encapsulation step S2, an adhesive agent 17 is applied to the perimeter of the substrate 11, or it is applied to the bonding side of the cover 21. Then, the cover 21 is bonded to the substrate 11, thereby encapsulating the organic EL laminated body 15 and other elements. Finally, an inspection step S3 is performed if necessary, thus obtaining an organic EL panel according to the present invention.

An organic EL panel according to the present invention and a method of manufacturing the organic EL panel will be concluded as follows.

Firstly, the present invention provides an organic EL panel having a substrate and an organic EL laminated body formed on the substrate, the organic EL laminated body being formed by interposing at least one organic layer between a pair of electrodes, the organic EL panel further including a cover for protecting the organic EL laminated body from the outside air, characterized in that: a least one desiccating member is provided within the cover and separated from the organic EL laminated body; and a concave portion is formed on one surface of the desiccating member, the one surface being orientated to face the organic EL laminated body. Further, the present invention provides a method of manufacturing an organic EL panel, comprising device formation step of forming, on a substrate, an organic EL laminated body including a pair of electrodes and at least one organic layer interposed between the pair of electrodes; and encapsulation step of bonding a cover to the substrate for protecting the organic EL laminated body from the outside air, characterized in that: at least one desiccating member is introduced into the cover prior to the encapsulation step; and a concave portion is formed on one surface of the desiccating member, the one surface being orientated to face the organic EL laminated body.

By virtue of the above features, even if the desiccating member expands because it absorbs moisture, the exposed side of the desiccating member would not project towards the organic EL laminated body. Therefore, it is possible to constantly keep an interval between the organic EL laminated body and the desiccating member at a distance which is equal to or larger than a predetermined value. In this way, it becomes unnecessary to provide a large clearance (for expansion) between the organic EL laminated body and the desiccating member, thus making it possible to produce an organic EL panel having a thin thickness. Further, since the desiccating member can avoid its contact with the organic EL laminated body, it is possible to ensure a sufficient working life for the organic EL panel.

Secondly, in the organic EL panel of the present invention, the desiccating member is a hygroscopic molded body attached to the inner surface of the cover, the hygroscopic molded body has a concave surface facing the organic EL laminated body. Further, in the method of manufacturing the organic EL panel of the present invention, the desiccating member is a hygroscopic molded body attached to the inner surface of the cover, one surface of the desiccating member facing the organic EL laminated body is formed by forming the surface into concave shape. By virtue of these features, it becomes possible to easily form a concave portion on the desiccating member's one surface facing the organic EL laminated body, thereby obtaining the organic EL panel which has the features mentioned above.

Thirdly, in the organic EL panel of the present invention, the desiccating member is a hygroscopic molded body attached to the inner surface of the cover, the hygroscopic molded body has a plurality of concave portions formed on its one surface facing the organic EL laminated body. Further, in the method of manufacturing the organic EL panel of the present invention, the desiccating member is a hygroscopic molded body attached to the inner surface of the cover, one surface of the hygroscopic molded body facing the organic EL laminated body is formed by forming a plurality of concave portions thereon. By virtue of these features, it is possible to effectively form concave portions even on a large size desiccating member to be provided within a large size cover of a large size display panel.

Fourthly, in the organic EL panel of the present invention, the inner surface of the cover is formed with at least one attachment section adapted to receive the hygroscopic molded body. Further, in the method of manufacturing the organic EL panel of the present invention, the inner surface of the cover is provided with at least one attachment section, the hygroscopic molded body is attached to the at least one attachment section. By virtue of these features, it becomes possible to exactly attach the desiccating member consisting of a hygroscopic molded body to each attachment section, so as to exactly prevent an undesired contact between the desiccating member and the organic EL laminated body. Moreover, since the formation of the at least one attachment section makes it possible to reduce the internal space of the cover, each desiccating member is allowed to be made compact in size.

Fifthly, a drop prevention sheet for preventing the drop of desiccating member is provided between the desiccating member and the organic EL laminated body. By virtue of this feature, it becomes possible to exactly prevent an undesired contact between the organic EL laminated body and the desiccating member by means of the drop prevention sheet, thereby further completing the present invention.

### EXAMPLE

Next, detailed description will be given to explain an example concerning the above-described embodiments of the present invention.

[Desiccating Member]

Each of the desiccating members 18, 22, 32, 42, and 52 is a hygroscopic molded body containing a desiccant and a resin component.

As a desiccant, it is allowed to use a material having a function of absorbing at least a moisture. Preferably, a desiccant is a compound capable of chemically absorbing a moisture and maintaining itself in a solid state even after having absorbed a moisture. In practice, such a compound may be a metal oxide, an inorganic acid salt of a metal, or an organic acid salt of a metal. Particularly, such a compound is at least one of an alkaline earth metal oxide and a sulfate. As an alkaline earth metal oxide, it is allowed to use calcium oxide (CaO), barium oxide (BaO), and magnesium oxide (MgO), etc. As a sulfate, it is allowed to use lithium sulfate (Li₂SO₄), sodium sulfate (Na₂SO₄), calcium sulfate (CaSO₄), magnesium sulfate (MgSO₄), a cobalt sulfate (CoSO₄), gallium sulfate (Ga₂(SO₄)₃), titanium sulfate (Ti₂ (SO₄)), nickel sulfate (NiSO₄), etc. In addition, a desiccant can also be an organic material having a moisture-absorbing property.

On the other hand, a resin component can be any desired resin material, provided that it will not hamper the moisture removal function as a desiccant. Preferably, such a resin component is a material having a high permeability (having a low air-barrier ability, especially an air permeable resin). For example, it is allowed to use a high molecular material, such as a polyolefine resin, a polyacryl resin, a polyacrylonitrile resin, a polyamide resin, a polyester resin, an epoxy resin, and a polycarbonate resin. However, it is preferable to use a polyolefine resin. In more detail, it is possible to use polyethylene, polypropylene, polybutadiene, polyisoprene, as well as their copolymers.

Here, desiccant and resin contents can be set in view of what substances are to be used. Usually, if a total amount of desiccant and resin is 100 wt %, desiccant content can be 30-85 wt % and resin content can be 70-15 wt %. Preferably, desiccant content is 40-80 wt % and resin content is 60-20 wt %. More preferably, desiccant content is 50-70 wt % and resin content is 50-30 wt %.

A hygroscopic molded body can be produced by sufficiently mixing the needed components and forming the obtained mixture into a desired shape. At this time, it is preferable to dry a desiccant and a resin in advance before they are mixed together. Further, when a resin is mixed, the resin can be heated (if necessary) into a molten state.

In the present embodiment of the present invention, it is preferable for a hygroscopic molded body to be formed by molding a mixture consisting of a desiccant and a resin (without containing any solvent). Namely, if a hygroscopic molded body is produced by using materials not containing a third component such as a solvent, it is possible to avoid some troubles (for example, remaining solvent will be absorbed into the desiccant and thus degrade the performance of the desiccant, or the remaining solvent will volatile within a cover with the passing of time) due to the presence of such third component in the molded body.

A method of attaching a desiccating member (hygroscopic molded body) to the inner surface of the cover should not receive any limitation, provided that the method is effective to form a firm attachment. For example, it is possible to use a well-known adhesive agent (preferably, an adhesive agent not containing a solvent) to bond the desiccating member to the cover, to thermally fuse the desiccating member onto the cover, or to fix the desiccating member to the cover by means of screw or the like.

[Organic EL Device]

An organic EL device is comprised of an organic EL laminated body 15 mounted on the substrate 11 and including the first electrode 12, the organic layer 13, and the second electrode 14 laminated one above another. The structure concerned and the materials related are described in detail below.

(a) Substrate

The substrate 11 is preferable to be a plate-like member or a film-like member having a predetermined transparency, and can be formed by glass or plastic.

(b) Electrodes

If an organic EL panel is a bottom emission type in which light is emitted from the substrate 11 side, the first electrode 12 is an anode consisting of a transparent electrode, while the second electrode 14 is a cathode consisting of a metal electrode. The anode is formed by depositing or sputtering ITO, ZnO or the like, while the cathode is formed by depositing or sputtering a metal, a metal oxide, a metal fluoride, or an alloy (all having a mall work function) For example, it is possible to form a single-layer structure of Al, In or Mg, or a laminated structure of LiO₂/Al, by vapor deposition or sputtering.

(c) Organic Layer

When the first electrode 12 is used as an anode and the second electrode 14 is used as a cathode, the organic layer 13 is usually formed into a laminated structure including hole transporting layer/luminescent layer/electron transporting layer. Here, hole transporting layer, luminescent layer and electron transporting layer can be such that each consists of single one layer or several layers. Alternatively, hole transporting layer and/or electron transporting layer may be omitted. Further, the organic layer 13 may include an organic functional layer such as a hole injection layer, an electron injection layer, a hole barrier layer, and an electron barrier layer, according to an actual purpose.

The material of the organic layer 13 can be suitably selected in view of an actual application of an organic EL device. Although an example is described below, the present invention should not be limited by such an example.

The hole transporting layer is formed by any one of known compounds, provided that its hole mobility is high. In detail, the various known compounds are all organic compounds including a porphyrin compound such as copper phthalocyanine, an aromatic tertiary amine such as 4,4′-bis [N-(1-naphthyl)-N-phenylamino]-biphenyl (NPB), a stilbene compound such as 4-(di-p-tolylmino)-4′-[4-(di-p-tolylmino)styryl]stilbenzene, a triazole derivative, a styryl amine compound. Moreover, it is also possible to use a high molecular dispersed material formed by dispersing an amount of low molecular organic material (for hole transportation) in a predetermined amount of high molecular material such as polycarbonate.

The luminescent layer is formed by any one of known luminescent materials. In detail, it is allowed to use fluorescent organic materials, including an aromatic dimethylidyne compound such as 4,4′-bis(2,2′-diphenyl vinyl)-biphenyl (DPVBi), a styrylbenzene compound such as 1,4-bis (2-methyl styryl) benzene, a triazole derivative such as 3-(4-biphenyl)-4-phenyl 5-t-butylphenyl 1,2,4-triazole (TAZ), an anthraquinone derivative, and a fluorenone derivative. Further, it is also possible to use a fluorescent organic metal oxide such as (8-hydroxyquinolynate) aluminum complex (Alq₃), and a high molecular material such as polyfluorenes and polyvinyl carbazoles (PVK). Moreover, it is allowed to employ an organic material capable of utilizing (for the purpose of luminescence) a phosphorescence from triplet excitons of a platinum complex or an iridium complex (Japanese Patent Application Publication No. 2001-520450). Besides, it is also possible for the luminescent layer to further contain hole transportation material, electron transportation material, additives (a donor, an acceptor, etc.), or a luminescent dopant. Alternatively, these materials may be dispersed in high molecular material or inorganic material.

The electron transporting layer can be formed by any one of known compounds, provided that it has a function of transporting electrons from the cathodes into the luminescent layer. In detail, it is allowed to use an organic material such as a nitro-substituted fluorenone derivative and an anthraquino dimethan derivative, a metal complex of an 8-quinolinol derivative, and a metal phthalocyanine, etc.

The above-mentioned hole transporting layer, luminescent layer, and electron transporting layer can be formed through a wet process such as spin coating, dipping, ink-jet, screen printing, or a dry process such as vapor deposition and laser transferring.

(d) Cover

The covers 16, 21, 31, 41, and 51 can be formed by any desired materials, preferably glass or metal.

(e) Adhesive Agent

The adhesive agent 17 can be thermal-setting type, chemical-setting type (two-liquid mixing), or light (ultraviolet light) setting type, and it is allowed to use an acryl resin, an epoxy resin, a polyester, a polyolefine. Particularly, it is preferable to use an ultraviolet-setting epoxy resin. Besides, an appropriate amount (about 0.1 to 0.5 wt %) of granular spacers (preferably, glass or plastic particles) having a particle size of 1-100 μm is mixed into the adhesive agent, and such an adhesive agent is applied by using a dispenser or the like.

(f) Display Types of Organic EL Panel

The organic EL laminated body 15 may form a single one organic EL device serving as one pixel. However, it is also possible for a plurality of such organic EL laminated bodies to be arranged to form a plurality of organic EL devices serving as a plurality of pixels.

In a display type involving a plurality of organic EL devices serving as a plurality of pixels, it is possible to perform a luminescence of a single one color or several different colors. Particularly, in order to realize an organic EL panel capable of performing a luminescence of several different colors, it is allowed to form luminescence functional layers of two or more colors, involving the formation of three kinds of luminescence functional layers corresponding to RGB (providing different colors). It is also possible to combine a color conversion layer (based on a color filter or a fluorescent material) into a luminescence functional layer of a single color which is white or blue (CF manner, CCM manner) Further, it is possible to irradiate the luminescent area of a single-color luminescence functional layer with an electromagnetic wave or the like so as to realize a plural-luminescences (photo breeching manner). On the other hand, an organic EL device may be driven in a passive manner or an active manner.

While there has been described what are at present considered to be preferred embodiments of the present invention, it will be understood that various modifications may be made thereto, and it is intended that the appended claims cover all such modifications as fall within the true spirit and scope of the invention.

1. An organic EL panel having a substrate and an organic EL laminated body formed on the substrate, said organic EL laminated body being formed by interposing at least one organic layer between a pair of electrodes, said organic EL panel further including a cover for protecting the organic EL laminated body from the outside air, characterized in that:
at least one desiccating member is provided within the cover and separated from the organic EL laminated body; and
a concave portion is formed on one surface of the desiccating member, said one surface being orientated to face the organic EL laminated body.

2. The organic EL panel according to claim 1, wherein the desiccating member is a hygroscopic molded body attached to the inner surface of the cover, the hygroscopic molded body has a concave surface facing the organic EL laminated body.

3. The organic EL panel according to claim 1, wherein the desiccating member is a hygroscopic molded body attached to the inner surface of the cover, the hygroscopic molded body has a plurality of concave portions formed on its one surface facing the organic EL laminated body.

4. The organic EL panel according to claim 2 or 3, wherein the inner surface of the cover is formed with at least one attachment section adapted to receive the hygroscopic molded body.

5. The organic EL panel according to any one of claims 1, 2 or 3, wherein a drop prevention sheet for preventing the drop of desiccating member is provided between the desiccating member and the organic EL laminated body.

6. A method of manufacturing an organic EL panel, including device formation step of forming, on a substrate, an organic EL laminated body including a pair of electrodes and at least one organic layer interposed between the pair of electrodes; and encapsulation step of bonding a cover to the substrate for protecting the organic EL laminated body from the outside air, characterized in that:
at least one desiccating member is introduced into the cover prior to the encapsulation step; and
a concave portion is formed on one surface of the desiccating member, said one surface being orientated to face the organic EL laminated body.

7. The method according to claim 6, wherein the desiccating member is a hygroscopic molded body attached to the inner surface of the cover, one surface of the desiccating member facing the organic EL laminated body is formed by forming the surface into concave shape.

8. The method according to claim 6, wherein the desiccating member is a hygroscopic molded body attached to the inner surface of the cover, one surface of the hygroscopic molded body facing the organic EL laminated body is formed by forming a plurality of concave portions thereon.

9. The method according to claim 7 or 8, wherein the inner surface of the cover is provided with at least one attachment section, the hygroscopic molded body is attached to the at least one attachment section.

10. The method according to any one of claims 6, 7 or 8, wherein a drop prevention sheet for preventing the drop of desiccating member is provided between the desiccating member and the organic EL laminated body.

11. The organic EL panel according to claim 4, wherein a drop prevention sheet for preventing the drop of desiccating member is provided between the desiccating member and the organic EL laminated body.

12. The method according to claim 9, wherein a drop prevention sheet for preventing the drop of desiccating member is provided between the desiccating member and the organic EL laminated body.
